(19) United States
(12) Patent Application Publication
(10) Pub. No.: US 2010/0032831 A1
(43) Pub. Date: Feb. 11, 2010

(54) BUMP STRUCTURE FOE SEMICONDUCTOR DEVICE

(75) Inventor: Byung-Jin Park, Chungbuk (KR)

Correspondence Address: HOSOON LEE, 9600 SW OAK ST. SUITE 525, TIGARD, OR, 97223, US

(73) Assignee: NEPES CORPORATION, Chungbuk (KR)

(21) Appl. No.: 12/517,555

(22) PCT Filed: Feb. 12, 2008
(86) PCT No.: PCT/KR08/00816

§ 371 Date: Jun. 3, 2009

(30) Foreign Application Priority Data
Feb. 28, 2007 (KR) 10-2007-0020040
Feb. 12, 2008 (KR) PCT/KR2008/000816

(51) Int. Cl. H01L 23/498

(52) U.S. Cl. 257/737; 257/E23.068

(57) ABSTRACT

There is provided a bump structure for a semiconductor device, comprising a first metal layer, and a second metal layer electrically connected to the first metal layer so as to be integrally formed with the first metal layer, and electrically connected to electrode pads of the semi-conductor device, in which the second metal layer is composed of one or more metals or alloys having the melting point higher than the melting point of the first metal layer or the eutectic temperature of the first metal layer and another substance when the first metal layer makes a fusion reaction to the surface of the another substance. Preferably, the second metal layer may have a thickness greater than that of the first metal layer. The bump structure may further comprise a diffusion prevention layer between the first metal layer and the second metal layer.

### TECHNICAL FIELD

The present invention relates to a bump structure for a semiconductor device, and more particularly, to a new bump structure which minimizes the spread phenomenon of its top portion, has a physically high supporting force and is suitable for realizing fine pitches.

### BACKGROUND ART

Much diverse research has been conducted towards the miniaturization and mass production of semiconductor packages in order to realize the production of semiconductor chips with higher integration, higher performance and higher speed. In a semiconductor package, for example, which has been proposed as a result of those efforts, semiconductor chip pads are electrically connected to electrode terminals of a printed circuit board, directly through bumps formed on the semiconductor chip pads, and composed of solder or metal materials.

According to application methods, semiconductor packages using solder bumps are classified into two types: a flip chip ball grid array (FCBGA) and a wafer level chip scale package (WLCSP). Typical methods applied for semiconductor packages using bumps composed of a metal material include a chip-on-glass and a tape carrier package (TCP).

In the flip chip ball grid array type, a semiconductor package is completed through sticking solder balls to the bottom of a substrate where a semiconductor chip is contacted so as to be electrically connected to the electrode terminals of a printed circuit board, after electrically connecting solder bumps in contact with semiconductor chip pads to pads of the substrate, and performing an underfill process to protect the solder bumps from external environments or mechanical problems. In the wafer level chip scale package (WLCSP), electrode pads are redistributed or reconfigured and the size of a chip is fabricated so as to be the same as the size of a package, for a light, thin, short and small product through using the bump of a metal material.

In the aforementioned various semiconductor package technologies, the structure of a bump is very important in realizing light, thin, short and small packages and fine pitches. However, when a metal used for the bump structure is fused with an external circuit board for electrical connection and as a result, the bump structure is seriously deformed, a bridge occurs between adjacent electrodes or the bump structure or package structure is contaminated or damaged. Consequently, this causes serious problems of decreasing the manufacturing yield and deteriorating the function of a semiconductor device.

For example, in FIG. 1, a bump structure 40 is formed on a substrate 10 where an electrode pad 20 is exposed by a dielectric layer 30. When the bump structure 40 is electrically connected to an external circuit board or another semiconductor device, a top surface (which is indicated as part ‘X’ in FIG. 2) of the bump structure 40 is seriously deformed by partial fusion.

Furthermore, as illustrated in FIG. 2, its structural stability becomes weak so that the shape of a bump structure 40 is seriously deformed. When the undesirably-deformed bump structure 40 is connected to other bump structures 40 around or infiltrates or contacts with the preformed structure of the substrate or wiring, it causes an electrical failure.

When a top portion of the bump structure spreads out in a horizontal direction (‘horizontal spread’) by the fusion, this generates the electrical connection between adjacent electrodes. The horizontal spread of the top portion of the bump structure not only obstructs the operative characteristics of a semiconductor device but also places limits on the application of a device design with fine pitches and a process thereof.

### DISCLOSURE OF INVENTION

### Technical Problem

Therefore, the present invention is directed to provide a new bump structure for a semiconductor device, which prevents a top portion of the bump structure from the spreading in a horizontal direction (horizontal spread), and the deformation in a vertical direction (vertical deformation) and improves a physical supporting force.

Another object of the present invention is to provide a bump structure for a semiconductor device, which prevents the bridge between adjacent electrodes and prevents the contamination or damage of components formed in the semiconductor device during a semiconductor packaging process with fine pitches, so that the yield increases and the performance deterioration decreases.

### Technical Solution

In accordance with an aspect of the present invention, the present invention provides a bump structure for a semiconductor device, comprising: a first metal layer electrically connected to various substrates including a printed circuit board, an electrical component or a mechanical component; and a second metal layer electrically connected to the first metal layer so as to be integrally formed with the first metal layer and electrically connected to electrode pads of the semiconductor device, in which the second metal layer is composed of one or more metals or alloys having the melting point higher than the melting point of the first metal layer or the eutectic temperature of the first metal layer and another substance when the first metal layer makes a fusion reaction to the surface of the another substance.

Preferably, the second metal layer may have a thickness greater than that of the first metal layer. For example, the second metal layer may have a thickness greater than one time that of the first metal layer. Preferably, the second metal layer may be formed so as to have a vertical thickness greater than 1.5 to 2 times that of the first metal layer, thereby increasing the structural stability of the bump structure and improving the spread of the first metal layer by its fusion.

The bump structure may further include a diffusion prevention layer between the first metal layer and the second metal layer. The bump structure may further include a solder layer on the first metal layer.

In accordance with another aspect of the present invention, the present invention provides a bump structure for a semiconductor device, comprising: a first metal layer electrically connected to various substrates including a printed circuit board, an electrical component or a mechanical component; and a second metal layer electrically connected to the first metal layer so as to be integrally formed with the first metal layer and electrically connected to electrode pads of the semiconductor device, in which the second metal layer is greater in vertical thickness than the first metal layer.

The present invention provides the multilayer bump structure including two or more layers. In accordance with the present invention, the bump structure minimizes the spread phenomenon caused by the fusion of the farthest outer layer of the bump structure when it is electrically connected to external circuit boards or other semiconductor devices, by differentiating the physical or chemical properties of a conductive substance composing each layer. Furthermore, the mechanical and/or physical stability of the bump structure is improved. Therefore, the bump structure is suitable for realizing the semiconductor package with fine pitches and reduces its manufacturing costs by replacing expensive bump materials with other inexpensive materials.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a sectional view of a bump structure formed of a single metal;

FIG. 2 is a schematic sectional view of the bump structure which spreads out at its top portion in a horizontal direction;

FIG. 3 is a sectional view of a bump structure according to an embodiment of the present invention;

FIG. 4 is a sectional view of a bump structure according to another embodiment of the present invention;

FIG. 5 is a sectional view of the bump structure contacting with an external circuit board; and

FIG. 6 is a sectional view of the bump structure electrically connected to the external circuit board.

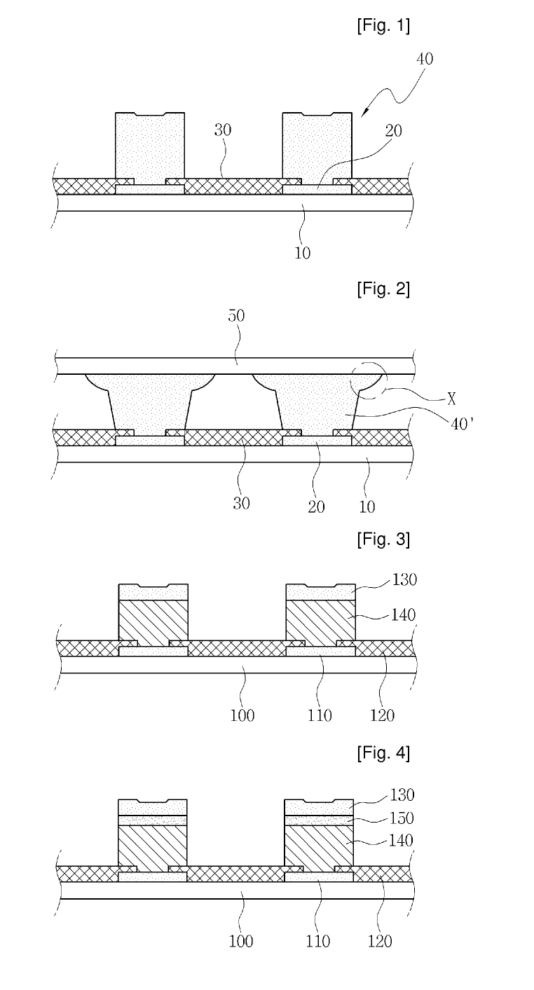

### MODE FOR THE INVENTION

The present invention will now be described more fully hereinafter with reference to the accompanying drawings, in which preferred embodiments of the invention are shown.

FIG. 3 is a sectional view of a bump structure according to an embodiment of the present invention. A first metal layer 130 and a second metal layer 140, which form a bump structure, are stacked to be integrally formed on a locally-exposed electrode pad 110 while other part of the electrode pad 110 is covered by a dielectric layer 120, at a predetermined region on the surface of a substrate 100, such as a printed circuit board or a silicon substrate and the like. The electrode pad may be formed at one end of wiring (not shown) which is redistributed inside the substrate 100.

The first metal layer 130 is less in vertical thickness than the second metal layer 140, and the first metal layer 130 and the second metal layer 140 are respectively formed of one or more metals having high conductivity.

The first metal layer 130 may use, for example, a metal or an alloy which is high in conductivity. In the embodiment of the present invention, Au is used but the present invention is not limited thereto. The first metal layer 130 may have a height from several tens of to several hundreds of ? and the height may be flexibly applicable depending on the substrate structure. Although not illustrated in FIG. 3, a solder layer may be further formed on the first metal layer 130 and the solder layer may be composed of any one substance selected from an eutectic solder (Sn/37Pb), a high lead solder (Sn/95Pb) and a lead free solder (Sn/Ag, Sn/Cu, Sn/Zn, Sn/Zn/Bi, Sn/Ag/Cu or Sn/Ag/Bi).

When the first metal layer 130 forms electrical connection by physically contacting with an external circuit board or another semiconductor device and the like, preferably, the second metal layer 140 may have a melting point higher than the eutectic temperature upon fusion on the contact surface. When the first metal layer 130 is electrically connected to silicon which is the material of the semiconductor substrate or another conductive substance and the like, an eutectic reaction generates by the fusion on the contact surface. In this case, the fusion generates at a temperature lower than the melting point of the first metal layer. The first metal layer 130 spreads out in a horizontal direction by its fusion, so that the area of the contact interface increases.

For example, when Au is used as the first metal layer 130 and silicon is the material of the external circuit board to be connected to the bump structure, the eutectic reaction of Au—Si generates on the contact interface. Then, the second metal layer may use all metals having a metal point higher than 363? which is the eutectic temperature of Au—Si. In the embodiment of the present invention, Cu is used as the second metal layer 140 but the present invention is not limited thereto. The second metal layer 140 may use various metals, such as titanium or titanium alloy, chrome or chrome alloy, copper or copper alloy, nickel or nickel alloy, gold or gold alloy, aluminum or aluminum alloy, vanadium or vanadium alloy, and the like.

When the first metal layer 130 spreads out in the horizontal direction by its fusion, the second metal layer 140 provides a physical supporting force under the first metal layer 130 and prevents the first metal layer 130 from excessively spreading out, so that one bump structure is prevented from being electrically connected to adjacent bump structures.

Further, since the second metal layer 140 forms one integrated stack structure while it supports the first metal layer 130 under the first metal layer 130, a relative thickness rate of the first metal layer 130 is reduced, compared with the bump structure formed of the first metal layer 130 only. In result, the bump structure comprising the first metal layer and the second metal layer greatly reduces the costs required for forming a bump structure using an expensive metal as the first metal layer 130. For example, the multilayer bump structure formed by stacking the first metal layer 130 and the second metal layer 140 has the effect of reducing the material cost by about 3 to 4 times or more, compared with that of the bump structure formed of only the first metal layer 130 using Au.

FIG. 4 is a sectional view of a bump structure according to another embodiment of the present invention. The bump structure of FIG. 4 is formed by stacking three layers, unlike that of the embodiment of FIG. 3.

In FIG. 4, a diffusion prevention layer 150 is additionally interposed between a first metal layer 130 and a second metal layer 140. The diffusion prevention layer 150 improves the bonding force between the first metal layer 130 and the second metal layer 140 and prevents diffusion. The diffusion prevention layer 150 may use materials which are generally used as a diffusion prevention layer and a bonding layer, such as nickel, titanium, chrome, copper, vanadium, aluminum, gold, cobalt, manganese, palladium, or alloys thereof. The diffusion prevention layer 150 may be formed as a single layer or a composite layer.

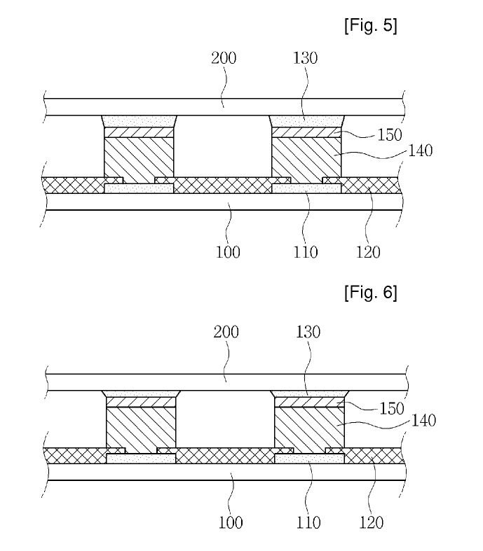

FIGS. 5 and 6 respectively illustrate the electrical connection structure between a semiconductor device and another semiconductor device (or external circuit board), which is formed through the bump structure according to the present invention.

As illustrated in FIG. 5, another semiconductor device or external circuit board 200 is placed to be close to a substrate 100 where the bump structure is formed. The surface of the another semiconductor device or external circuit board 200 contacts with the first metal layer 130 which is the top of the bump structure. When the first metal layer 130 of the bump structure is fused with the surface of the another semiconductor device or external circuit board 200 by heat treatment, the first metal layer 130 is partially melted to form the physical bonding and electrical connection.

Since the second metal layer 140 under the first metal layer 130 has the melting point greater than the eutectic temperature of the mixture of the first metal layer 130 and the surface of the another semiconductor device or external circuit board 200, the physical shape of the second metal layer 140 does not change during the fusion process and therefore the second metal layer 140 maintains the bump structure firmly.

Consequently, as illustrated in FIG. 6, although the first metal layer 130 forming a top portion of the bump structure partially spreads out in the horizontal direction, the shape of the whole bump structure keeps the secure state which does not greatly change from the original state. Specifically, even though the first metal layer 130 is considerably melted during the bonding process, the melting is limited to the top end of the second metal layer 140. Therefore, many problems caused by the melting of the first metal layer 130 are solved, the yield of products is improved and the reliance of the process is achieved.

Furthermore, the space needed for the electrical connection between the semiconductor device and the external circuit board 200 or another semiconductor device is secured by controlling the height of the second metal layer 140 acting as a kind of a spacer. Further, the horizontal spread is minimized by controlling the height of the first metal layer 130. For these purposes, preferably, the second metal layer 140 may have a vertical thickness greater than that of the first metal layer 130, and more preferably, the second metal layer 140 may have a vertical thickness greater than 1.5 to 2 times that of the first metal layer 130.

Furthermore, excellent uniformity in terms of the height of each bump structure prevents a bonding failure between the bump structure and the external circuit board 200 or another semiconductor device. Specifically, since the horizontal spread of the first metal layer 130 is prevented, the semiconductor package with fine pitches is realized.

The present invention can be applied to broad semiconductor devices and semiconductor packages. Furthermore, the semiconductor devices may include silicon wafer devices including metal wiring, electronic devices including two or three dimensional structures formed of silicon, various other metals, and the like.

As described above, the present invention provides the multilayer bump structure including two or more layers. In accordance with the present invention, the bump structure minimizes the spread phenomenon caused by the fusion of the farthest outer layer of the bump structure when it is electrically connected to external circuit boards or other semiconductor devices, by differentiating the physical or chemical properties of a conductive substance composing each layer. Furthermore, the mechanical and/or physical stability of the bump structure is improved. Therefore, the bump structure is suitable for realizing the semiconductor package with fine pitches and reduces its manufacturing cost by replacing expensive bump materials with other inexpensive materials.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

1. A bump structure for a semiconductor device, comprising:
a first metal layer electrically connected to various substrates including a printed circuit board, an electrical component or a mechanical component; and
a second metal layer electrically connected to the first metal layer so as to be integrally formed with the first metal layer, and electrically connected to electrode pads of the semiconductor device,
wherein the second metal layer is composed of one or more metals or alloys having the melting point higher than the melting point of the first metal layer or the eutectic temperature of the first metal layer and another substance when the first metal layer makes a fusion reaction to the surface of the another substance.

2. The bump structure of claim 1, wherein the second metal layer has a thickness greater than that of the first metal layer.

3. The bump structure of claim 1, further comprising one or more diffusion prevention layers between the first metal layer and the second metal layer.

4. The bump structure of claim 3, wherein the diffusion prevention layer is composed of any one or more substances selected from nickel, titanium, chrome, copper, vanadium, aluminum, gold, cobalt, manganese and palladium, and alloys thereof.

5. The bump structure of claim 1, further comprising a solder layer on the first metal layer.

6. The bump structure of claim 1, wherein the first metal layer is composed of Au.

7. The bump structure of claim 1, wherein the second metal layer is composed of any one or more substances selected from titanium or titanium alloy, chrome or chrome alloy, copper or copper alloy, nickel or nickel alloy, gold or gold alloy, aluminum or aluminum alloy and vanadium or vanadium alloy.

8. The bump structure of claim 1, wherein the electrode pads of the semiconductor device is formed at one end of redistributed wiring.

9. A bump structure for a semiconductor device, comprising:
a first metal layer electrically connected to various substrates including a printed circuit board, an electrical component or a mechanical component; and
a second metal layer electrically connected to the first metal layer so as to be integrally formed with the first metal layer, and electrically connected to electrode pads of the semiconductor device,
wherein the second metal layer is greater in vertical thickness than that of the first metal layer.

10. The bump structure of claim 9, wherein the second metal layer is composed of one or more metals or alloys having the melting point higher than the melting point of the first metal layer or the eutectic temperature of the first metal layer and another substance when the first metal layer makes a fusion reaction to the surface of the another substance.

11. The bump structure of claim 9, further comprising one or more diffusion prevention layers between the first metal layer and the second metal layer.

12. The bump structure of claim 9, further comprising a solder layer on the first metal layer.
